(19) United States
(12) Patent Application Publication
(10) Pub. No.: US 2024/0333228 A1
(43) Pub. Date: Oct. 3, 2024

(54) DOHERTY AMPLIFIER CIRCUIT

(71) Applicant: Murata Manufacturing Co., Ltd., Kyoto (JP)

(72) Inventors: Shohei IMAI, Kyoto (JP); Tetsurou ASHIDA, Kyoto (JP)

(21) Appl. No.: 18/621,706

(22) Filed: Mar. 29, 2024

(30) Foreign Application Priority Data
Mar. 31, 2023 (JP) 2023-058638
Oct. 31, 2023 (JP) 2023-186707

(51) Int. Cl. H03F 1/02; H03F 3/21; H03G 3/30

(52) U.S. Cl. CPC H03F 1/0288; H03F 3/211; H03G 3/3042; H03G 2201/103

(57) ABSTRACT

A Doherty amplifier circuit includes a first integrated circuit and a second integrated circuit connected to the first integrated circuit. One of the first integrated circuit and the second integrated circuit includes a carrier amplifier that amplifies a radio-frequency signal, a peak amplifier that amplifies the radio-frequency signal, a variable gain control circuit that controls a gain of the radio-frequency signal based on a drive level signal that indicates a drive level of the carrier amplifier, and a bias circuit that inputs a bias based on an output from the variable gain control circuit to the peak amplifier. The first integrated circuit on a silicon die includes at least the variable gain control circuit.

### CROSS REFERENCE TO RELATED APPLICATION

This application claims priority from Japanese Patent Application No. 2023-058638 filed on Mar. 31, 2023, and Japanese Patent Application No. 2023-186707 filed on Oct. 31, 2023. The contents of these applications are incorporated herein by reference in their entireties.

### BACKGROUND ART

The present disclosure relates to a Doherty amplifier circuit.

A Doherty amplifier circuit has been known as a high-efficiency power amplifier circuit. In general, the Doherty amplifier circuit has a configuration of parallel connection of a carrier amplifier that operates irrespective of a power level of an input signal and a peak amplifier that is turned off when the power level of the input signal is low and is turned on when the power level is large. Of this configuration, when a power level of a radio-frequency input signal is large, the carrier amplifier operates while retaining saturation at a saturated output power level. Thus, the Doherty amplifier circuit can improve efficiency as compared to a usual power amplifier circuit.

The following U.S. Patent Application Publication No. 2016/0241209, U.S. Patent Application Publication No. 2020/0028472, and Japanese Unexamined Patent Application Publication No. 2019-41277 disclose techniques for controlling a bias of a peak amplifier.

The technique disclosed in U.S. Patent Application Publication No. 2016/0241209 is configured to detect saturation of a carrier amplifier by using a bias circuit of the carrier amplifier and to control a bias circuit of a peak amplifier depending on a detected signal.

The technique disclosed in U.S. Patent Application Publication No. 2020/0028472 is configured to detect saturation of a carrier amplifier by using an output signal from the carrier amplifier and to control a bias circuit of a peak amplifier depending on a detected signal.

The technique disclosed in Japanese Unexamined Patent Application Publication No. 2019-41277 is configured to control a bias circuit of a peak amplifier depending on a radio-frequency input signal level inputted to a Doherty amplifier circuit or on a radio-frequency input signal level inputted to a carrier amplifier.

### BRIEF SUMMARY

Of the techniques disclosed in U.S. Patent Application Publication No. 2016/0241209 and U.S. Patent Application Publication No. 2020/0028472, several tens of nanoseconds are required as time for response from the circuit for detecting the saturation of the carrier amplifier. Accordingly, the following problems may occur. When a radio-frequency input signal having a momentary (which is time considerably shorter than several tens of nanoseconds) increase in power is inputted to the Doherty amplifier circuit, for example, a moment of saturation of the carrier amplifier is likely to occur during the period of several tens of seconds from the start of saturation of the carrier amplifier to variation in bias point of the peak amplifier. Accordingly, there may be a case where it is not possible to keep high quality of the radio-frequency output signal from the Doherty amplifier circuit. On the other hand, when the Doherty amplifier circuit is applied to a communication apparatus, there may be a case where it is not possible to keep high communication quality.

Although the technique disclosed in Japanese Unexamined Patent Application Publication No. 2019-41277 is operated depending on the radio-frequency input signal level, the radio-frequency input signal level is detected by using the bias circuit and a response speed is basically considered to be slow. Hence, there may possibly be a case where it is not possible to keep high quality of the radio-frequency output signal from the Doherty amplifier circuit.

In the meantime, it is also suitable to suppress an increase in circuit scale of the Doherty amplifier circuit.

The present disclosure suppresses a deterioration in quality of a radio-frequency output signal while preventing an increase in circuit scale of a Doherty amplifier circuit.

A Doherty amplifier circuit according to an aspect of the present disclosure includes: a first integrated circuit; and a second integrated circuit connected to the first integrated circuit, in which one of the first integrated circuit and the second integrated circuit includes a carrier amplifier that amplifies a radio-frequency signal, a peak amplifier that amplifies the radio-frequency signal, and a variable gain control circuit that controls a gain of the radio-frequency signal based on a drive level signal that indicates a drive level of the carrier amplifier, a state of operation of the peak amplifier is controlled based on an output from the variable gain control circuit, and the first integrated circuit on a silicon die includes at least the variable gain control circuit.

Of the present disclosure, it is possible to suppress a deterioration in quality of a radio-frequency output signal while preventing an increase in circuit scale of a Doherty amplifier circuit.

### BRIEF DESCRIPTION OF THE DRAWINGS

FIG. 1 is a diagram illustrating a configuration of a Doherty amplifier circuit of a first embodiment;

FIG. 2 is a diagram illustrating a configuration of a Doherty amplifier circuit of a second embodiment;

FIG. 3 is a diagram illustrating a configuration of a Doherty amplifier circuit of a third embodiment;

FIG. 4 is a diagram illustrating a configuration of a Doherty amplifier circuit of a fourth embodiment;

FIG. 5 is a diagram illustrating a configuration example of a multiplier in FIG. 4;

FIG. 6 is a diagram illustrating a configuration example of a variable phase shifter in FIG. 4;

FIG. 7 is a diagram illustrating a configuration example of a frequency divider in FIG. 4;

FIG. 8 is a diagram illustrating a configuration of a Doherty amplifier circuit of a fifth embodiment;

FIG. 9 is a diagram illustrating a configuration example of a multiplication circuit in FIG. 8;

FIG. 10 is a diagram illustrating examples of a signal to be outputted from the multiplication circuit in FIG. 9;

FIG. 11 is a diagram illustrating a configuration of a Doherty amplifier circuit of a sixth embodiment;

FIG. 12 is a diagram illustrating a configuration of a Doherty amplifier circuit of a seventh embodiment;

FIG. 13 is a diagram illustrating a configuration of a Doherty amplifier circuit of an eighth embodiment; and

FIG. 14 is a diagram illustrating a configuration of a peak amplifier in the Doherty amplifier circuit of the eighth embodiment.

### DETAILED DESCRIPTION

Embodiments of the present disclosure will be described below in detail based on the drawings. In the following description of the respective embodiments, constituents identical or equivalent to those in other embodiments will be denoted by the same reference signs and explanations thereof will be simplified or omitted. The respective embodiments do not intend to limit the present disclosure. Meanwhile, the constituents of the respective embodiments include those that are easily replaceable by those skilled in the art or those which are substantially the same. The configurations described below can be combined as appropriate. It is possible to omit, replace, or change a configuration within the range not departing from the gist of the disclosure. From the second embodiment on, a description concerning items that are common to those in the first embodiment will be omitted as appropriate and different features will be explained. In particular, the same operation and effects originating from the same configuration will not be stated sequentially in the respective embodiments.

### First Embodiment

### Configuration

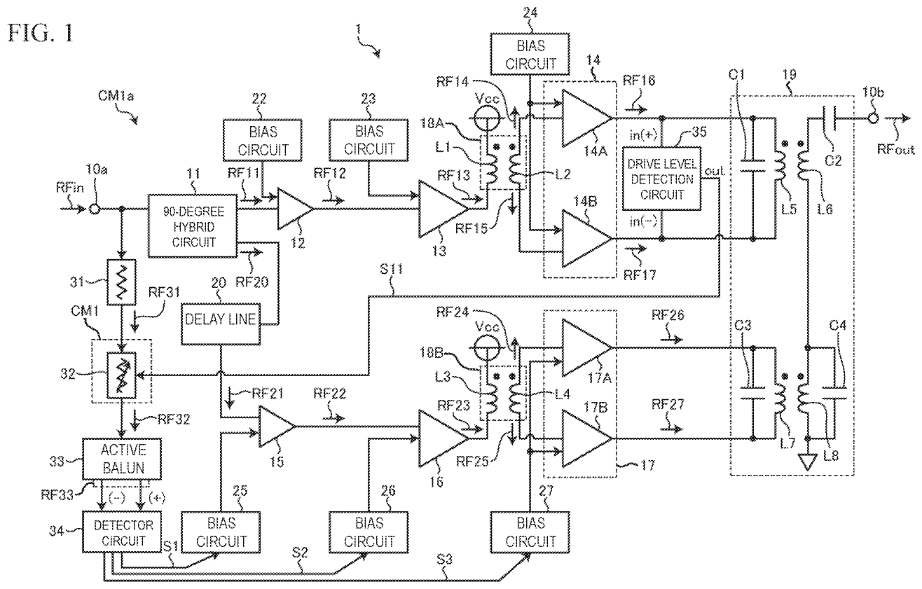

FIG. 1 is a diagram illustrating a configuration of a Doherty amplifier circuit of a first embodiment. In FIG. 1, a Doherty amplifier circuit 1 of the first embodiment amplifies a radio-frequency signal RFin inputted to an input terminal 10a and outputs a radio-frequency signal RFout from an output terminal 10b.

The Doherty amplifier circuit 1 includes a 90-degree hybrid circuit 11, a carrier amplifier 12 at an initial stage (a driver stage), a carrier amplifier 13 at an intermediate stage, a balun 18A, a carrier amplifier 14 at a final stage (a power stage), a delay line 20, a peak amplifier 15 at an initial stage, a peak amplifier 16 at an intermediate stage, a balun 18B, a peak amplifier 17 at a final stage, a coupler 19, and bias circuits 22 to 27.

The carrier amplifier 14 is a differential amplifier that includes a carrier amplifier 14A of a first phase and a carrier amplifier 14B of a second phase. The peak amplifier 17 is a differential amplifier that includes a peak amplifier 17A of a first phase and a peak amplifier 17B of a second phase. In the present disclosure, an output signal from one amplifier in the differential amplifier and an output signal from the other amplifier therein preferably have a difference in voltage amplitude equal to or below 3 dB and a phase difference in a range from 90° to 270°.

In the present embodiment, the number of stages of the Doherty amplifier circuit 1 is set to three stages. However, the present disclosure is not limited thereto. The number of stages of the Doherty amplifier circuit 1 may be set to one stage, two stages, or four or more stages.

In the present embodiment, each of the carrier amplifier 12 and the carrier amplifier 13 is set to a single ended amplifier. However, the present disclosure is not limited thereto. Each of the carrier amplifier 12 and the carrier amplifier 13 may be a differential amplifier.

In the present embodiment, the carrier amplifier 14 is set to the differential amplifier. However, the present disclosure is not limited thereto. The carrier amplifier 14 may be a single ended amplifier.

In the present embodiment, each of the peak amplifier 15 and the peak amplifier 16 is set to a single ended amplifier. However, the present disclosure is not limited thereto. Each of the peak amplifier 15 and the peak amplifier 16 may be a differential amplifier.

In the present embodiment, the peak amplifier 17 is set to the differential amplifier. However, the present disclosure is not limited thereto. The peak amplifier 17 may be a single ended amplifier.

The 90-degree hybrid circuit 11 divides the radio-frequency signal RFin inputted to the input terminal 10a into radio-frequency signals RF11 and RF20 having phases about 90° different from each other. The radio-frequency signal RF11 is inputted to the carrier amplifier 12. The radio-frequency signal RF20 is inputted to the delay line 20. The delay line 20 delays the radio-frequency signal RF20 for a predetermined time period and outputs the signal as a radio-frequency signal RF21. The radio-frequency signal RF21 inputted to the peak amplifier 15. Here, the expression “about 90°” is assumed to include not only the phase at 90° but also phases in a range of 90°+45°. The 90-degree hybrid circuit 11 corresponds to a “distribution circuit” of the present disclosure.

It is exemplified that the phase of the radio-frequency signal RF21 is delayed by 90° from that of the radio-frequency signal RF11. It is exemplified that electric power of the radio-frequency signal RF11 is equal to electric power of the radio-frequency signal RF21.

The bias circuit 22 provides a bias to the carrier amplifier 12. The carrier amplifier 12 outputs a radio-frequency signal RF12 obtained by amplifying the radio-frequency signal RF11 to the carrier amplifier 13. The bias circuit 23 provides a bias to the carrier amplifier 13. The carrier amplifier 13 outputs a radio-frequency signal RF13 obtained by amplifying the radio-frequency signal RF12 to one end of a first winding wire L1 of the balun 18A.

Another end of the first winding wire L1 of the balun 18A is electrically connected to a power supply Vcc. The balun 18A converts radio-frequency signal RF13 into a radio-frequency signal RF14 and a radio-frequency signal RF15 constituting differential signals and outputs the respective signals from both ends of a second winding wire L2.

The bias circuit 24 provides a bias to the carrier amplifiers 14A and 14B. The carrier amplifier 14A outputs a radio-frequency signal RF16 obtained by amplifying the radio-frequency signal RF14 to the coupler 19. The carrier amplifier 14B outputs a radio-frequency signal RF17 obtained by amplifying the radio-frequency signal RF15 to the coupler 19.

The bias circuit 25 provides a bias to the peak amplifier 15. The peak amplifier 15 outputs a radio-frequency signal RF22 obtained by amplifying the radio-frequency signal RF21 to the peak amplifier 16.

The bias circuit 26 provides a bias to the peak amplifier 16. The peak amplifier 16 outputs a radio-frequency signal RF23 obtained by amplifying the radio-frequency signal RF22 to one end of a first winding wire L3 of the balun 18B.

Another end of the first winding wire L3 of the balun 18B is electrically connected to the power supply Vcc. The balun 18B converts radio-frequency signal RF23 into a radio-frequency signal RF24 and a radio-frequency signal RF25 constituting differential signals and outputs the respective signals from both ends of a second winding wire L4.

The bias circuit 27 provides a bias to the peak amplifiers 17A and 17B. The peak amplifier 17A outputs a radio-frequency signal RF26 obtained by amplifying the radio-frequency signal RF24 to the coupler 19. The peak amplifier 17B outputs a radio-frequency signal RF27 obtained by amplifying the radio-frequency signal RF25 to the coupler 19.

Meanwhile, the Doherty amplifier circuit 1 includes an attenuator 31, a variable gain control circuit 32, an active balun 33, and a detector circuit 34. The attenuator 31 attenuates the radio-frequency signal RFin and outputs the attenuated signal as a radio-frequency signal RF31. The variable gain control circuit 32 attenuates the radio-frequency signal RF31 based on a detection signal S11 and outputs the attenuated signal as a radio-frequency signal RF32. The active balun 33 outputs a radio-frequency signal RF33 being a differential signal to the detector circuit 34.

In the present embodiment, the active balun 33 is configured to output the radio-frequency signal RF33. However, the present disclosure is not limited thereto. The active balun 33 may be configured to output a single ended radio-frequency signal. On the other hand, the attenuator 31 may be deleted in a case where attenuation with the variable gain control circuit 32 is sufficient.

The coupler 19 includes first winding wires L5 and L7, second winding wires L6 and L8, a capacitor C1 connected in parallel to the first winding wire L5, a capacitor C2 connected in series to the second winding wire L6, a capacitor C3 connected in parallel to the first winding wire L7, and a capacitor C4 connected in parallel to the second winding wire L8. One end of the first winding wire L5 is connected to an output end of the carrier amplifier 14A. Another end of the first winding wire L5 is connected to an output end of the carrier amplifier 14B. One end of the first winding wire L7 is connected to an output end of the peak amplifier 17A. Another end of the first winding wire L7 is connected to an output end of the peak amplifier 17B. One end of the second winding wire L6 is connected to one end of the capacitor C2. Another end of the second winding wire L6 is connected to one end of the second winding wire L8 and one end of the capacitor C4. Another end of the second winding wire L8 and another end of the capacitor C4 are connected to a reference potential. A ground potential is exemplified as the reference potential. However, the present disclosure is not limited thereto. The coupler 19 couples the radio-frequency signals RF16, RF 17, RF26 and RF27 and outputs the radio-frequency signal RFout from the output terminal 10b.

A drive level detection circuit 35 detects a drive level (an operating level) of the carrier amplifier 14 based on the radio-frequency signals RF16 and RF17, and outputs the detection signal S11 indicating the drive level of the carrier amplifier 14 to the variable gain control circuit 32. The detection signal S11 may be a signal (an inversion signal) that complementarily varies with the drive level of the carrier amplifier 14.

The radio-frequency signal RF31 and the detection signal S11 are inputted to the variable gain control circuit 32. Instead of the radio-frequency signal RF31, the radio-frequency signal RF11 or the radio-frequency signal RF20 may be inputted to the variable gain control circuit 32.

The variable gain control circuit 32 attenuates the radio-frequency signal RF31 based on the detection signal S11, and outputs the radio-frequency signal RF32 to the active balun 33. When the detection signal S11 indicates that the carrier amplifier 14 is close to a saturation level, for example, it is exemplified that the variable gain control circuit 32 outputs the radio-frequency signal RF32 without necessarily attenuating the radio-frequency signal RF31 very much. Meanwhile, when the detection signal S11 indicates that the carrier amplifier 14 is not close to the saturation level, for example, it is exemplified that the variable gain control circuit 32 outputs the radio-frequency signal RF32 while significantly attenuating the radio-frequency signal RF31.

The detector circuit 34 outputs control signals S1, S2, and S3 based on the radio-frequency signal RF33. The control signals S1, S2, and S3 are inputted to the bias circuits 25, 26, and 27, respectively. As described above, the bias circuits 25, 26, and 27 provide the biases to the peak amplifiers 15, 16, 17A, and 17B. That is to say, states of operation of the peak amplifiers 15, 16, 17A, and 17B are controlled by the control signals S1, S2, and S3. To be more precise, the peak amplifiers 15, 16, 17A, and 17B are controlled by the control signals S1, S2, and S3 based on the radio-frequency signal RF32 outputted from the variable gain control circuit 32 as to whether each peak amplifier takes on the state of operation (the state of amplification of the radio-frequency signal) or the state of non-operation (the state of non-amplification of the radio-frequency signal). Here, there is disclosed a configuration in which the control signals S1, S2, and S3 are inputted to the bias circuits 25, 26, and 27 of the peak amplifiers 15, 16, 17A, and 17B in the Doherty amplifier circuit 1. However, the control signals S1, S2, and S3 may be inputted directly to the peak amplifiers 15, 16, 17A, and 17B without necessarily passing the signals through the bias circuits 25, 26, and 27.

### Effects

The Doherty amplifier circuit 1 configured as described above includes a first integrated circuit CM1 provided with the variable gain control circuit 32, and a portion other than the first integrated circuit CM1. The first integrated circuit CM1 is formed on a silicon die. The portion other than the first integrated circuit CM1, that is to say, a portion outside frames formed from dashed lines in FIG. 1 will be defined as a “second integrated circuit”. The portion other than the variable gain control circuit 32 is formed in a second integrated circuit CM1a. The second integrated circuit CM1a is formed on a die other than the silicon die. The second integrated circuit CM1a is formed on a GaAs (gallium arsenide) die, for example. The second integrated circuit CM1a is connected to the first integrated circuit CM1. Here, it can be thought that the detector circuit 34 operates in a feedforward fashion in response to the radio-frequency signal RFin. By forming a portion concerning this feedforward on the silicon die, it is possible to increase control response by the bias circuits 25 and 26.

An area may be increased when the variable gain control circuit 32 is formed on a chip. Formation of the variable gain control circuit 32 in the first integrated circuit CM1 on the silicon die enables microfabrication of the variable gain control circuit 32 so that its footprint on the chip can be reduced. As a consequence, the entire Doherty amplifier circuit 1 to be formed on the chip can be reduced in size.

### Second Embodiment

### Configuration

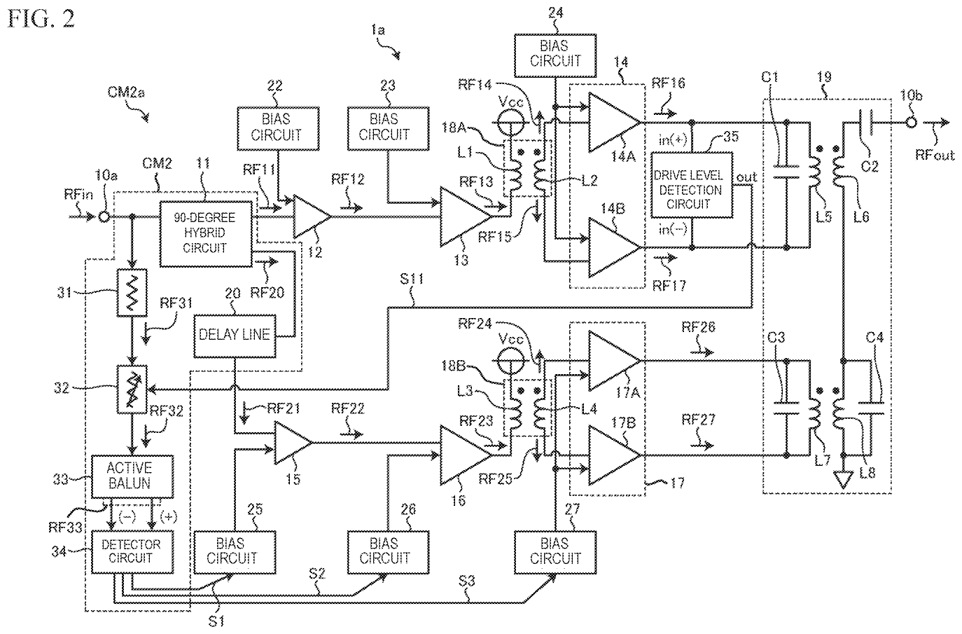

FIG. 2 is a diagram illustrating a configuration of a Doherty amplifier circuit of a second embodiment. A range of formation of a Doherty amplifier circuit 1a of the second embodiment illustrated in FIG. 2 on a silicon die is different from that of the Doherty amplifier circuit 1 of the first embodiment.

In the Doherty amplifier circuit 1 of the first embodiment described with reference to FIG. 1, the variable gain control circuit 32 is formed in the first integrated circuit CM1 on the silicon die. On the other hand, in the Doherty amplifier circuit 1a of the second embodiment illustrated in FIG. 2, the 90-degree hybrid circuit 11, the attenuator 31, the active balun 33, the detector circuit 34, and the delay line 20 are formed in a first integrated circuit CM2 on the silicon die together with the variable gain control circuit 32. A portion of the Doherty amplifier circuit 1a other than the first integrated circuit CM2 on the silicon die, that is to say, a portion outside frames formed from dashed lines indicated with reference sign “CM2” in FIG. 2, is formed in a second integrated circuit CM2a. The second integrated circuit CM2a is formed on a GaAs die, for example. The second integrated circuit CM2a is connected to the first integrated circuit CM2.

### Effects

When the 90-degree hybrid circuit 11, the attenuator 31, the active balun 33, the detector circuit 34, and the delay line 20 are formed in the first integrated circuit CM2 on the silicon die together with the variable gain control circuit 32, microfabrication of these constituents is enabled so that their footprints on the chip can be reduced. As a consequence, the entire Doherty amplifier circuit 1a to be formed on the chip can be reduced in size.

In the meantime, there may be a case where the variable gain control circuit 32, the active balun 33, and the detector circuit 34 require a current source. When this current source is formed in the first integrated circuit CM2 on the silicon die and the variable gain control circuit 32, the active balun 33, and the detector circuit 34 are formed in the second integrated circuit CM2a other than the first integrated circuit CM2 on the silicon die, it is suitable to prepare bumps for exchanging signals, which may hinder downsizing of the circuit. In this regard, the bumps for exchanging signals are optional when the relevant portions are formed in a lump in the first integrated circuit CM2 on the silicon die as in the present embodiment, so that the Doherty amplifier circuit 1a can be reduced in size.

### Third Embodiment

### Configuration

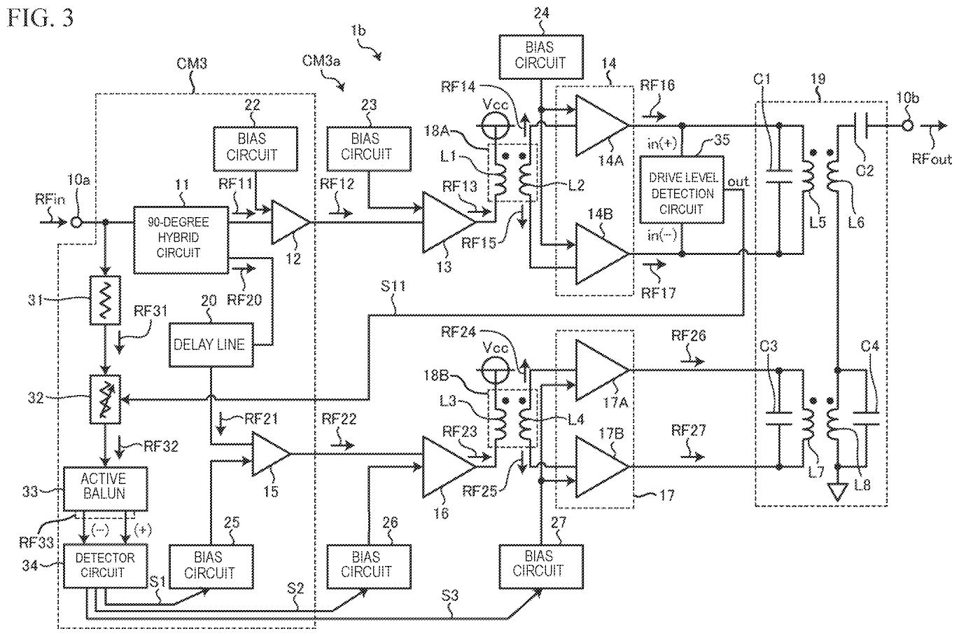

FIG. 3 is a diagram illustrating a configuration of a Doherty amplifier circuit of a third embodiment. A range of formation of a Doherty amplifier circuit 1b of the third embodiment illustrated in FIG. 3 on a silicon die is different from those of the Doherty amplifier circuit 1 of the first embodiment and the Doherty amplifier circuit 1a of the second embodiment.

In the Doherty amplifier circuit 1 of the first embodiment described with reference to FIG. 1, the variable gain control circuit 32 is formed in the first integrated circuit CM1 on the silicon die. Meanwhile, in the Doherty amplifier circuit 1a of the second embodiment illustrated in FIG. 2, the 90-degree hybrid circuit 11, the attenuator 31, the variable gain control circuit 32, the active balun 33, the detector circuit 34, and the delay line 20 are formed in the first integrated circuit CM2 on the silicon die. On the other hand, in the Doherty amplifier circuit 1b of the third embodiment illustrated in FIG. 3, the carrier amplifier 12 at a first stage, the peak amplifier 15 at a first stage, and the bias circuits 22 and 25 in the Doherty amplifier circuit 1a of the second embodiment are further formed on a first integrated circuit CM3 on a silicon die. A portion of the Doherty amplifier circuit 1b other than the first integrated circuit CM3 on the silicon die, that is to say, a portion outside frames formed from dashed lines indicated with reference sign “CM3” in FIG. 3, is formed in a second integrated circuit CM3a. The second integrated circuit CM3a is formed on a GaAs die, for example. The second integrated circuit CM3a is connected to the first integrated circuit CM3.

### Effects

When the respective constituents mentioned above are formed in the first integrated circuit CM3 on the silicon die, microfabrication of these constituents is enabled so that their footprints on the chip can be reduced. As a consequence, the entire Doherty amplifier circuit 1b to be formed on the chip can be reduced in size. Here, with reference to FIG. 1, the Doherty amplifier circuit 1 includes the first integrated circuit CM1 and the second integrated circuit CM1a connected to the first integrated circuit CM1. With reference to FIG. 2, the Doherty amplifier circuit 1a includes the first integrated circuit CM2 and the second integrated circuit CM2a connected to the first integrated circuit CM2. With reference to FIG. 3, the Doherty amplifier circuit 1b includes the first integrated circuit CM3 and the second integrated circuit CM3a connected to the first integrated circuit CM3. Moreover, one of the first integrated circuit CM1 (CM2 or CM3) and the second integrated circuit CM1a (CM2a or CM3a) includes the carrier amplifiers 12, 13, and 14 that amplify the radio-frequency signals, the peak amplifiers 15, 16, and 17 that amplify the radio-frequency signals, the variable gain control circuit 32 that controls a gain of the radio-frequency signal based on a drive level signal indicating the drive level of the carrier amplifier 14, and the bias circuits 25, 26, and 27 that input the biases based on the output from the variable gain control circuit 32 to the peak amplifiers. Accordingly, each of the first integrated circuit CM1 illustrated in FIG. 1, the first integrated circuit CM2 illustrated in FIG. 2, and the first integrated circuit CM3 illustrated in FIG. 3 at least includes the variable gain control circuit 32. Since the variable gain control circuit 32 that may increase the area when formed on the chip is formed in each of the first integrated circuits CM1, CM2, and CM3 on the silicon die, it is possible to downsize each of the Doherty amplifier circuit 1, the Doherty amplifier circuit 1a, and the Doherty amplifier circuit 1b. The same applies to the respective embodiments to be described below.

Meanwhile, in the Doherty amplifier circuit 1b, the carrier amplifier 12 at the first stage, the peak amplifier 15 at the first stage, and the bias circuits 22 and 25 are also formed together in the first integrated circuit CM3 on the silicon die. This makes it possible to reduce the number of the wiring and the bumps on the chip to be connected to the carrier amplifier 12 at the first stage, the peak amplifier 15 at the first stage, and the bias circuits 22 and 25. In general, the wiring and the bumps on the chip are apt to cause parasitic components. Accordingly, when the carrier amplifier 12 at the first stage and the peak amplifier 15 at the first stage provided outside the silicon die, that is to say, on the chip, operations of the carrier amplifier 12 at the first stage and the peak amplifier 15 at the first stage may be slowed down while being affected by these parasitic components. On the other hand, in the Doherty amplifier circuit 1b, the carrier amplifier 12 at the first stage, the peak amplifier 15 at the first stage, and the bias circuits 22 and 25 are formed in the first integrated circuit CM3 on the same silicon die as that on which the variable gain control circuit 32 and the like are provided. Thus, it is possible to minimize the parasitic components attributed to the wiring and the bumps on the chip and to increase operating speeds of the carrier amplifier 12 at the first stage and the peak amplifier 15 at the first stage.

### Fourth Embodiment

### Configuration

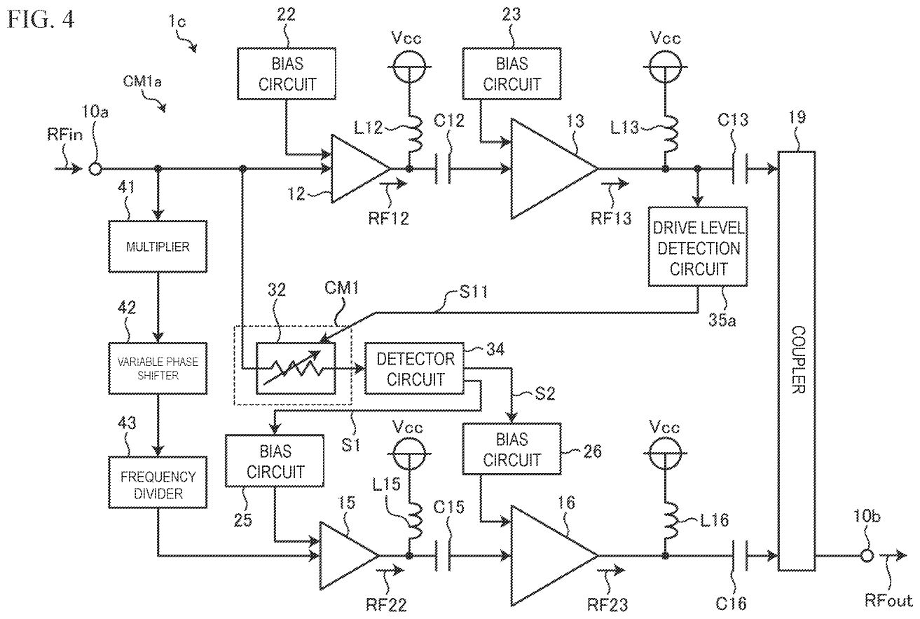

FIG. 4 is a diagram illustrating a configuration of a Doherty amplifier circuit of a fourth embodiment. A Doherty amplifier circuit 1c of the fourth embodiment is equivalent to the Doherty amplifier circuit 1 of the first embodiment which includes a multiplier 41, a variable phase shifter 42, and a frequency divider 43 instead of the 90-degree hybrid circuit. In the meantime, the Doherty amplifier circuit 1 of the first embodiment has the three-stage structures of both the carrier amplifiers and the peak amplifiers, whereas the number of stages in the Doherty amplifier circuit 1c of the fourth embodiment is two stages. In other words, the Doherty amplifier circuit 1c includes the carrier amplifier 12 at the driver stage, the carrier amplifier 13 at the power stage, the peak amplifier 15 at the driver stage, and the peak amplifier 16 at the power stage. Here, the Doherty amplifier circuit 1c of the fourth embodiment includes capacitors C12, C13, C15, and C16 for cutting off a direct current.

Moreover, the carrier amplifier 14 at the final stage and the peak amplifier 17 at the final stage of the Doherty amplifier circuit 1 of the first embodiment are each the differential amplifier. On the other hand, the carrier amplifier 13 at the power stage and the peak amplifier 16 at the power stage of the Doherty amplifier circuit 1c of the fourth embodiment are each a single ended amplifier.

The drive level detection circuit 35 of the Doherty amplifier circuit 1 of the first embodiment detects the drive level (the operating level) based on the radio-frequency signals being the differential signals. On the other hand, a drive level detection circuit 35a of the Doherty amplifier circuit 1c of the fourth embodiment detects the drive level (the operating level) by comparing the radio-frequency signal with a predetermined reference potential, for example.

A phase different at 90 degrees can be realized by using the multiplier 41, the variable phase shifter 42, and the frequency divider 43 as long as the bias circuits 25 and 26 can appropriately control the peak amplifiers 15 and 16. As a consequence, it is optional to provide the 90-degree hybrid circuit that causes an increase in circuit scale, so that the entire Doherty amplifier circuit 1c can be reduced in size.

### Multiplier

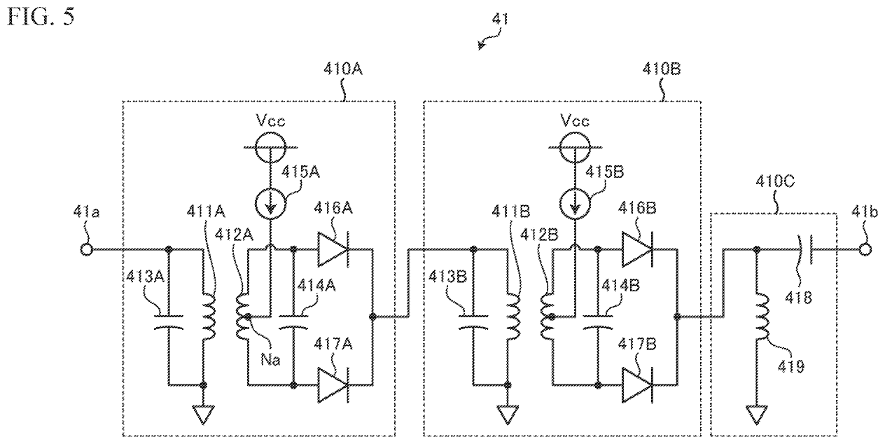

FIG. 5 is a diagram illustrating a configuration example of the multiplier 41 in FIG. 4. In FIG. 5, the multiplier 41 includes an input terminal 41a, a multiplier 410A at a precedent stage, a multiplier 410B at a subsequent stage, a high pass filter 410C, and an output terminal 41b.

The multiplier 410A at the precedent stage includes inductors 411A and 412A, capacitors 413A and 414A, a current source 415A, and diodes 416A and 417A.

One end of the inductor 411A is connected to the input terminal 41a and another end of the inductor 411A is connected to the reference potential. The inductor 411A and the inductor 412A are electromagnetically coupled to each other. The capacitor 413A is connected in parallel to the inductor 411A. The capacitor 414A is connected in parallel to the inductor 412A.

The current source 415A is connected to a midpoint Na of the inductor 412A. The current source 415A is connected to the power supply Vcc.

One end of the inductor 412A is connected to an anode of the diode 416A and another end of the inductor 412A is connected to an anode of the diode 417A. A cathode of the diode 416A is connected to a cathode of the diode 417A, and the cathodes are further connected to the multiplier 410B at the subsequent stage.

The multiplier 410B at the subsequent stage has the same configuration as that of the multiplier 410A at the precedent stage. Specifically, the multiplier 410B at the subsequent stage includes inductors 411B and 412B, capacitors 413B and 414B, a current source 415B, and diodes 416B and 417B. A cathode of the diode 416B is connected to a cathode of the diode 417B, and the cathodes are further connected to the high pass filter 410C.

The high pass filter 410C includes a capacitor 418 and an inductor 419. One end of the capacitor 418 is connected to one end of the inductor 419, and another end of the capacitor 418 is connected to the output terminal 41b. Another end of the inductor 419 is connected to the reference potential.

In the multiplier 410A at the precedent stage, when an alternating-current signal is inputted to the input terminal 41a, a current flows on the inductor 411A on a primary side. The current source 415A is connected to the midpoint Na of the inductor 412A on a secondary side, and two currents inverted to each other are thus obtained. By passing these two currents through the diodes 416A and 417A for a half cycle each, an alternating-current signal having a frequency twice larger is obtained. When this alternating-current signal having the frequency twice larger is inputted to the multiplier 410B at the subsequent stage, an alternating-current signal having a frequency even twice larger is obtained. In other words, the alternating-current signal having the frequency four times larger is obtained by using the multiplier 410A at the precedent stage and the multiplier 410B at the subsequent stage. The alternating-current signal having the frequency four times larger than the signal which is passed through the high pass filter 410C and is inputted to the input terminal 41a is outputted from the output terminal 41b.

### Phase Shifter

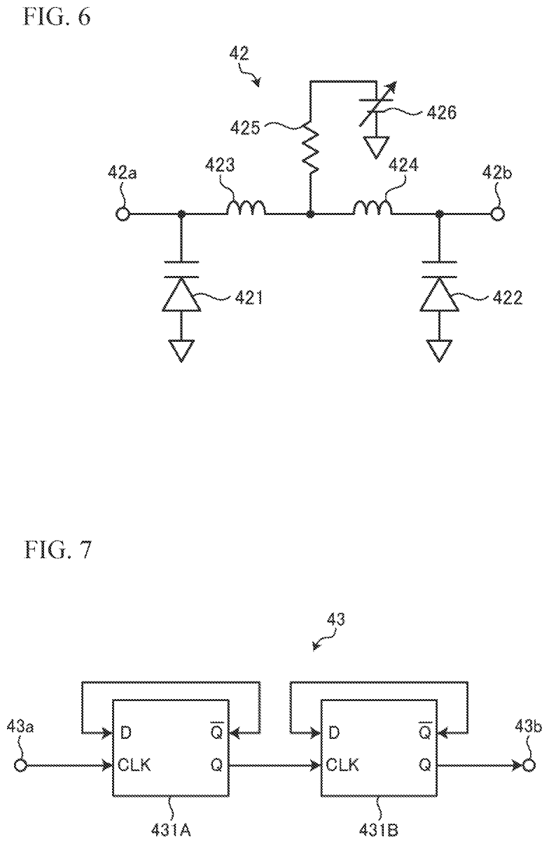

FIG. 6 is a diagram illustrating a configuration example of the variable phase shifter 42 in FIG. 4. The variable phase shifter 42 includes an input terminal 42a, variable capacitance diodes 421 and 422, inductors 423 and 424, a resistor 425, a variable voltage source 426, and an output terminal 42b.

A π-type filter circuit is formed by the variable capacitance diodes 421 and 422 as well as the inductors 423 and 424. A desired amount of phase shift can be realized by appropriately adjusting the variable voltage source 426.

### Frequency Divider

FIG. 7 is a diagram illustrating a configuration example of the frequency divider 43 in FIG. 4. In FIG. 7, the frequency divider 43 includes D-type flip-flop circuits 431A and 431B, an input terminal 43a, and an output terminal 43b.

The input terminal 43a is connected to a clock terminal CLK of the D-type flip-flop circuit 431A. An output terminal Q of the D-type flip-flop circuit 431A is connected to a clock terminal CLK of the D-type flip-flop circuit 431B. An output terminal Q of the D-type flip-flop circuit 431B is connected to the output terminal 43b. An inverted output terminal Q(−) of the D-type flip-flop circuit 431A is connected to a input terminal D of the D-type flip-flop circuit 431A. An inverted output terminal Q(−) of the D-type flip-flop circuit 431B is connected to an input terminal D of the D-type flip-flop circuit 431B.

The D-type flip-flop circuit 431A connected as described above retrieves a level of the input terminal D at a transition timing of a signal inputted to the clock terminal CLK, and outputs the signal from the output terminal Q. Since the input terminal D is connected to the inverted output terminal Q(−), the output terminal Q outputs a signal that is inverted at the transition timing of the signal inputted to the clock terminal CLK. As a consequence, the D-type flip-flop circuit 431A outputs a signal having a cycle that is ½ of a cycle of the signal to be inputted to the input terminal 43a.

The D-type flip-flop circuit 431B accepts the output from the D-type flip-flop circuit 431A as an input. The D-type flip-flop circuit 431B has the same configuration as that of the D-type flip-flop circuit 431A. As a consequence, a signal having a cycle that is ¼ of the cycle of the signal to be inputted to the input terminal 43a is outputted from the output terminal 43b by using the D-type flip-flop circuits 431A and 431B. In short, the frequency divider 43 operates as a quarter frequency divider.

Back to FIG. 4, in the Doherty amplifier circuit 1c, the variable gain control circuit 32 is formed in a first integrated circuit CM1 on a silicon die. A portion other than the first integrated circuit CM1 of the Doherty amplifier circuit 1c on the silicon die, that is to say, a portion outside a frame formed from a dashed line and indicated with reference sign “CM1” in FIG. 4 is formed in a second integrated circuit CM1a. The second integrated circuit CM1a is formed on a GaAs die, for example. The second integrated circuit CM1a is connected to the first integrated circuit CM1.

### Effects

As described above, the Doherty amplifier circuit 1c multiplies the frequency by 4 times with the multiplier 41 so as to pass through the variable phase shifter 42, and then the frequency is brought back to the original value with the frequency divider 43. A wavelength can be shortened since the frequency is high at a point of passage through the variable phase shifter 42. Accordingly, it is possible to reduce the areas for realizing the inductors included in the variable phase shifter 42. The wavelength is lengthened if the multiplier 41, the variable phase shifter 42, and the frequency divider 43 are not provided. In that case, the areas for forming the inductors are increased, thus increasing a circuit scale of the variable phase shifter 42. Of the above-described Doherty amplifier circuit 1c, it is possible to shorten the wavelength and to suppress the increase in circuit scale.

The area may be increased when the variable gain control circuit 32 is formed on the chip. When the variable gain control circuit 32 is formed in the first integrated circuit CM1 on the silicon die, microfabrication of the variable gain control circuit 32 is enabled so that its footprint on the chip can be reduced. As a consequence, the entire Doherty amplifier circuit 1c to be formed on the chip can be reduced in size.

Meanwhile, as with the Doherty amplifier circuit 1a described with reference to FIG. 2 or the Doherty amplifier circuit 1b described with reference to FIG. 3, the respective portions other than the variable gain control circuit 32 may be formed in the first integrated circuit CM2 or CM3 on the silicon die. When the respective portions are formed in the first integrated circuit on the silicon die, microfabrication of these portions is enabled so that their footprints on the chip can be reduced. As a consequence, the entire Doherty amplifier circuit 1c to be formed on the chip can be reduced in size.

### Fifth Embodiment

### Configuration

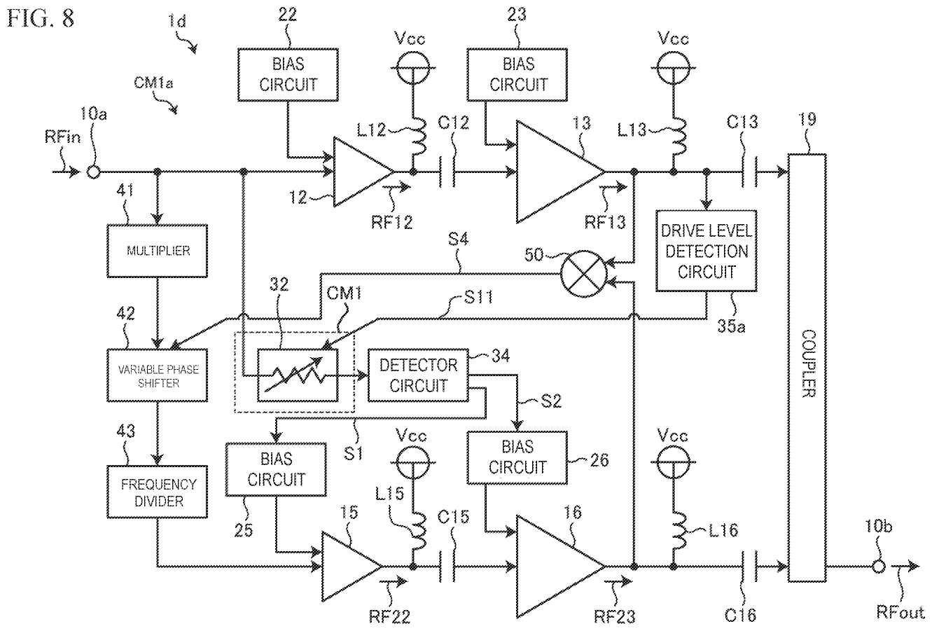

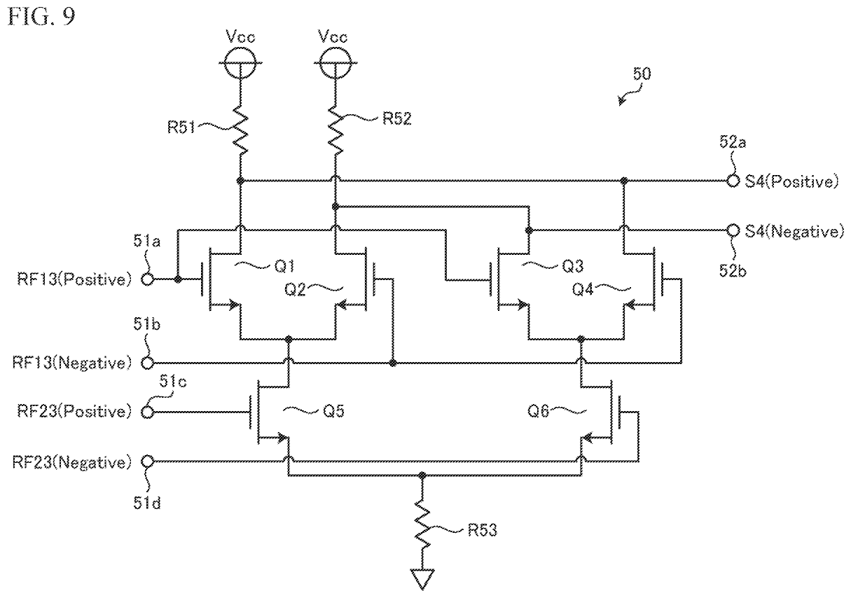

FIG. 8 is a diagram illustrating a configuration of a Doherty amplifier circuit 1d of a fifth embodiment. The Doherty amplifier circuit 1d of the fifth embodiment illustrated in FIG. 8 has a configuration of the Doherty amplifier circuit 1c of the fourth embodiment additionally provided with a multiplication circuit 50. The multiplication circuit 50 inputs the radio-frequency signal RF13 being the output from the carrier amplifier 13 and the radio-frequency signal RF23 being the output from the peak amplifier 16. The multiplication circuit 50 outputs a signal S4 obtained by multiplying the radio-frequency signal RF13 by the radio-frequency signal RF23. The signal S4 outputted from the multiplication circuit 50 is inputted to the variable phase shifter 42. The amount of phase shift of the variable phase shifter 42 is controlled by the signal S4. That is to say, the multiplication circuit 50 outputs a control signal based on the output signal from the carrier amplifier 13 (the radio-frequency signal RF13) and the output signal from the peak amplifier 16 (the radio-frequency signal RF23). Note that the multiplication circuit corresponds to a “control circuit” of the present disclosure.

### Multiplication Circuit

FIG. 9 is a diagram illustrating a configuration example of the multiplication circuit 50 in FIG. 8. The multiplication circuit 50 illustrated in FIG. 9 includes transistors Q1 to Q6, resistors R51, R52, and R53, input terminals 51a, 51b, 51c, and 51d, and output terminals 52a and 52b.

When drawing attention to the transistors Q1 and Q2, a drain of the transistor Q1 is connected to the power supply Vcc with the resistor R51 interposed therebetween, and a drain of the transistor Q2 is connected to the power supply Vcc with the resistor R52 interposed therebetween. Moreover, a source of the transistor Q1 is connected to a source of the transistor Q2. Accordingly, the transistor Q1 and the transistor Q2 constitute a differential amplifier circuit.

When drawing attention to the transistors Q3 and Q4, a drain of the transistor Q3 is connected to the power supply Vcc with the resistor R52 interposed therebetween, and a drain of the transistor Q4 is connected to the power supply Vcc with the resistor R51 interposed therebetween. Moreover, a source of the transistor Q3 is connected to a source of the transistor Q4. Accordingly, the transistor Q3 and the transistor Q4 constitute a differential amplifier circuit.

An output from the differential amplifier circuit formed from the transistors Q1 and 02 is inputted to a drain of the transistor Q5. Meanwhile, an output from the differential amplifier circuit formed from the transistors Q3 and Q4 is inputted to a drain of the transistor Q6. A source of the transistor Q5 is connected to a source of the transistor Q6, and the sources are connected to the reference potential with the resistor R53 interposed therebetween. Here, a current source may be connected instead of the resistor R53.

The radio-frequency signal RF13 outputted from the carrier amplifier 13 in FIG. 8 is inputted to the input terminal 51b. The radio-frequency signal RF23 outputted from the peak amplifier 16 in FIG. 8 is inputted to the input terminal 51d. When drawing attention to the transistor Q4 and the transistor Q6, the radio-frequency signal RF13 is applied to a gate of the transistor Q4 while the radio-frequency signal RF23 is applied to a gate of the transistor Q6, and the signal S4 obtained by multiplying these signals is outputted from the output terminal 52b.

Here, when the carrier amplifier 13 in FIG. 8 is a differential amplifier (not illustrated), the radio-frequency signal RF13 on a positive side is inputted to the input terminal 51a while the radio-frequency signal RF13 on a negative side is inputted to the input terminal 51b. Meanwhile, when the peak amplifier 16 in FIG. 8 is a differential amplifier (not illustrated), the radio-frequency signal RF23 on a positive side is inputted to the input terminal 51c while the radio-frequency signal RF23 on a negative side is inputted to the input terminal 51d. The signal S4 on the positive side obtained by multiplying the radio-frequency signal RF13 by the radio-frequency signal RF23 on the positive side is outputted from the output terminal 52a. The signal S4 on the negative side obtained by multiplying the radio-frequency signal RF13 by the radio-frequency signal RF23 on the negative side is outputted from the output terminal 52b. Here, when the carrier amplifier 13 and the peak amplifier 16 are not the differential amplifiers as illustrated in FIG. 8, the input terminal 51b and the input terminal 51d are used as described above without necessarily using the input terminals 51a and 51c.

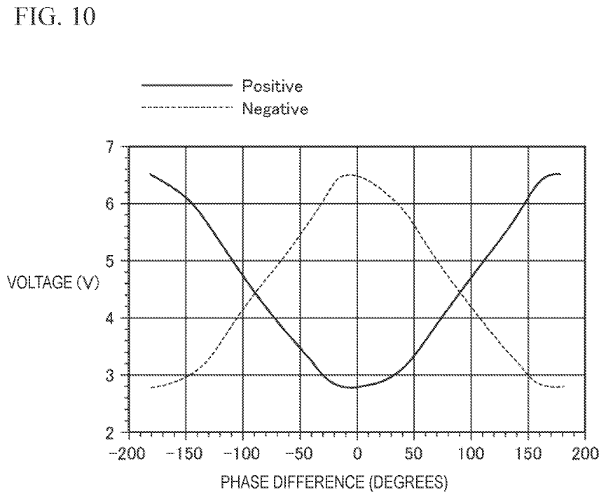

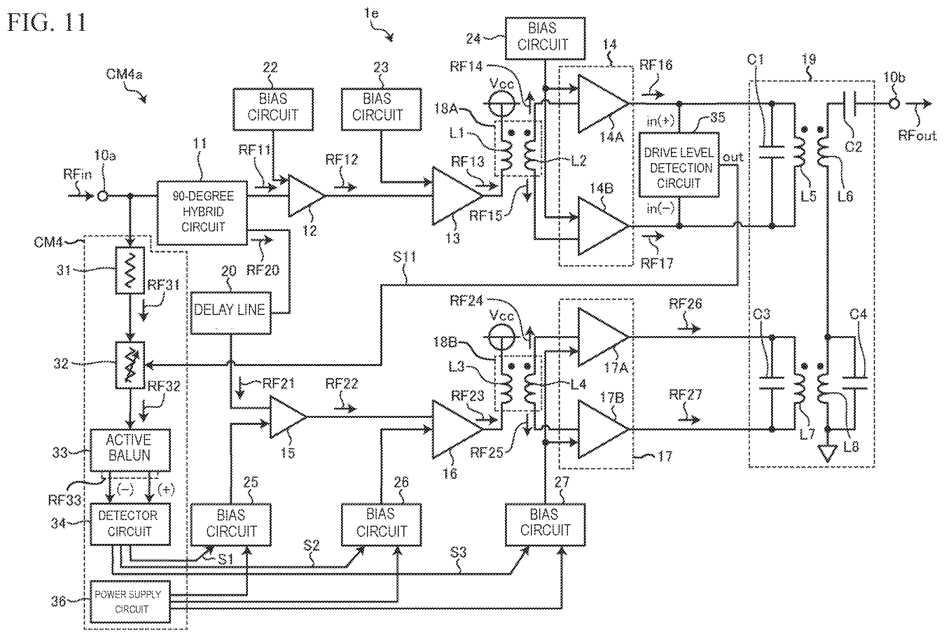

FIG. 10 is a diagram illustrating examples of the signal S4 to be outputted from the multiplication circuit 50 in FIG. 9. In FIG. 10, a horizontal axis indicates a phase difference (degrees) and a vertical axis indicates an output voltage (V). In FIG. 10, a solid line indicates the radio-frequency signal on the positive side and a dashed line indicates the radio-frequency signal on the negative side.

In FIG. 10, when drawing attention to the radio-frequency signal on the positive side indicated with the solid line, the voltage of the signal S4 is higher in the case where the phase difference is large as compared to the case where the phase difference is close to 0 degrees (the phase difference is small). Accordingly, the variable phase shifter 42 is controlled in such a way as to reduce the phase difference. Meanwhile, when drawing attention to the radio-frequency signal on the negative side indicated with the dashed line, the voltage of the signal S4 is higher in the case where the phase difference is small as compared to the case where the phase difference is large. In these manners, the variable phase shifter 42 is controlled in such a way as to reduce the phase difference.

In the meantime, in FIG. 10, a phase difference at −90 degrees is an ideal relationship in a case of a parallel synthesis by using the signals on both the positive side and the negative side. With reference to FIG. 10, both of the outputs on the positive side and the negative side are around 4.4 V in the case where the phase difference is equal to −90 degrees. Accordingly, the multiplier 41, the variable phase shifter 42, and the frequency divider 43 (see FIG. 8) are designed in advance such that the phase difference originating therefrom is equal to 90 degrees at 4.4 V. In the variable phase shifter 42, a reverse bias of a varactor diode used as a variable capacitance is increased when an applied voltage becomes larger, whereby a depletion layer expands so as to reduce the capacitance. In other words, a passing phase is reduced in accordance with the increase in applied voltage. The following effect is available by connecting the positive side of the output from the multiplication circuit 50 by using this action. For example, in a case where an output phase difference between the two amplifiers changes from the designed ideal value of −90 degrees to −80 degrees due to an effect of a certain factor (such as an individual difference between the amplifiers and a load fluctuation), the applied voltage to the variable phase shifter 42 changes from 4.4 V to 4.2 V. For this reason, the phase difference among the multiplier 41, the variable phase shifter 42, and the frequency divider 43 is increased from 90 degrees and reaches 100 degrees, for example.

In this way, the phase difference among the respective amplifiers which is reduced by an external factor can forcibly be corrected to the designed ideal value by the phase shifter. As a consequence, an effect of an improvement in resistance to environmental variations is obtained. Here, in a case of a serial type that uses one of the positive side and the negative side, the designed ideal phase difference is +90 degrees. Accordingly, the same effect as that of the above-mentioned parallel type is obtained by connecting the negative side.

Back to FIG. 8, the variable gain control circuit 32 being a portion of the Doherty amplifier circuit 1d is formed in a first integrated circuit CM1 on a silicon die. A portion other than the first integrated circuit CM1 of the Doherty amplifier circuit 1d on the silicon die, that is to say, a portion outside a frame formed from a dashed line and indicated with reference sign “CM1” in FIG. 8 is formed in a second integrated circuit CM1a. The second integrated circuit CM1a is formed on a GaAs die, for example. The second integrated circuit CM1a is connected to the first integrated circuit CM1.

### Effects

As described above, the phase difference can be maintained in an appropriate state by controlling the variable phase shifter 42 based on the signal S4 outputted from the multiplication circuit 50. As a consequence, even when a portion of the Doherty amplifier circuit 1d is formed in the first integrated circuit CM1 on the silicon die, it is possible to maintain the phase difference in the appropriate state, thereby maintaining quality of the radio-frequency signal.

### Sixth Embodiment

### Configuration

FIG. 11 is a diagram illustrating a configuration of a Doherty amplifier circuit 1e of a sixth embodiment. The Doherty amplifier circuit 1e of the sixth embodiment illustrated in FIG. 11 has a configuration equivalent to the Doherty amplifier circuit 1a of the second embodiment illustrated in FIG. 2, in which the attenuator 31, the variable gain control circuit 32, the active balun 33, and the detector circuit 34 are formed in a first integrated circuit CM4 on a silicon die. Moreover, a power supply circuit 36 is formed in the first integrated circuit CM4. A portion of the Doherty amplifier circuit 1e other than the first integrated circuit CM4 is formed in a second integrated circuit CM4a. The 90-degree hybrid circuit 11 and the delay line 20 are formed in the second integrated circuit CM4a. The second integrated circuit CM4a is formed on a GaAs (gallium arsenide) die, for example.

The power supply circuit 36 outputs a direct current. The direct current outputted from the power supply circuit 36 is inputted to the bias circuits 25, 26, and 27. The bias circuits 25, 26, and 27 are operated by an electric current inputted from the power supply circuit 36. The bias circuits 25, 26, and 27 provide the biases to the peak amplifiers 15, 16, 17A, and 17B as described above.

### Effects

Of the Doherty amplifier circuit 1e of the sixth embodiment, power consumption can be reduced by forming the respective constituents in the first integrated circuit CM4 on the silicon die.

### Seventh Embodiment

### Configuration

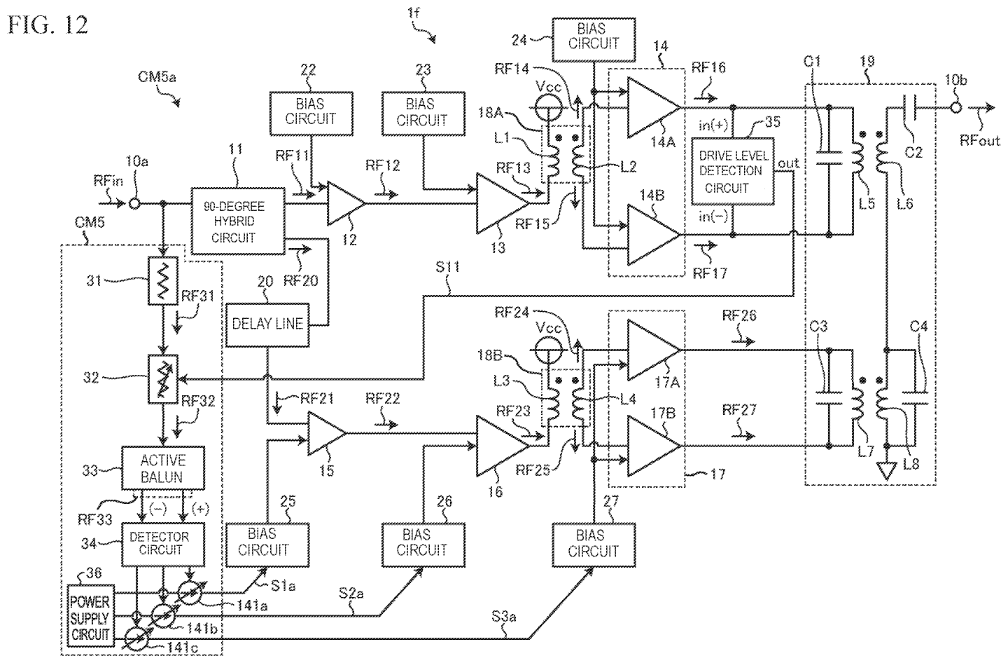

FIG. 12 is a diagram illustrating a configuration of a Doherty amplifier circuit 1f of a seventh embodiment. The Doherty amplifier circuit 1f of the seventh embodiment illustrated in FIG. 12 has a configuration in which variable current sources 141a, 141b, and 141c are provided between the power supply circuit 36 and the bias circuits 25, 26, and 27 of the Doherty amplifier circuit 1e of the sixth embodiment illustrated in FIG. 11. As illustrated in FIG. 12, the attenuator 31, the variable gain control circuit 32, the active balun 33, the detector circuit 34, the power supply circuit 36, and the variable current sources 141a, 141b, and 141c are formed in a first integrated circuit CM5 on a silicon die. A portion of the Doherty amplifier circuit 1f other than the first integrated circuit CM5 is formed in a second integrated circuit CM5a.

The variable current sources 141a, 141b, and 141c are controlled by an output from the detector circuit 34. The direct current outputted from the power supply circuit 36 is controlled by the variable current sources 141a, 141b, and 141c based on the output from the detector circuit 34, and then inputted to the bias circuits 25, 26, and 27. Accordingly, a control signal Sla for operating and controlling the bias circuit 25 can be sent from the power supply circuit 36 to the bias circuit 25 by using one signal line. A control signal S2a for operating and controlling the bias circuit 26 can be sent from the power supply circuit 36 to the bias circuit 26 by using one signal line. A control signal S3a for operating and controlling the bias circuit 27 can be sent from the power supply circuit 36 to the bias circuit 27 by using one signal line.

Here, in the case of the Doherty amplifier circuit 1e of the sixth embodiment described with reference to FIG. 11, six signal lines are suitable for transmission from the first integrated circuit CM4 to the second integrated circuit CM4a. Specifically, six signal lines are required for sending the three signals S1, S2, and S3 to be inputted to the bias circuits 25, 26, and 27 and for sending the three direct currents outputted from the power supply circuit 36. Accordingly, each of the first integrated circuit CM4 and the second integrated circuit CM4a needs to be provided with six electrodes corresponding to these six signal lines.

On the other hand, in the case of the Doherty amplifier circuit 1f of the seventh embodiment illustrated in FIG. 12, three signal lines are sufficient for sending the signals Sla, S2a, and S3a to the respective bias circuits 25, 26, and 27. Three electrodes corresponding to these three signal lines only need to be provided to the first integrated circuit CM4 and the second integrated circuit CM4a, respectively. Since the number of the electrodes to be provided to each of the first integrated circuit CM4 and the second integrated circuit CM4a is decreased, it is possible to reduce the areas required for the electrodes.

### Effects

Of the Doherty amplifier circuit 1f of the seventh embodiment, it is possible to reduce the areas required for the electrodes as compared to the Doherty amplifier circuit 1e of the sixth embodiment illustrated in FIG. 11, so that the area of the entire Doherty amplifier circuit 1f can be reduced.

### Eighth Embodiment

A peak amplifier including an enable terminal will be described in an eighth embodiment.

### Configuration

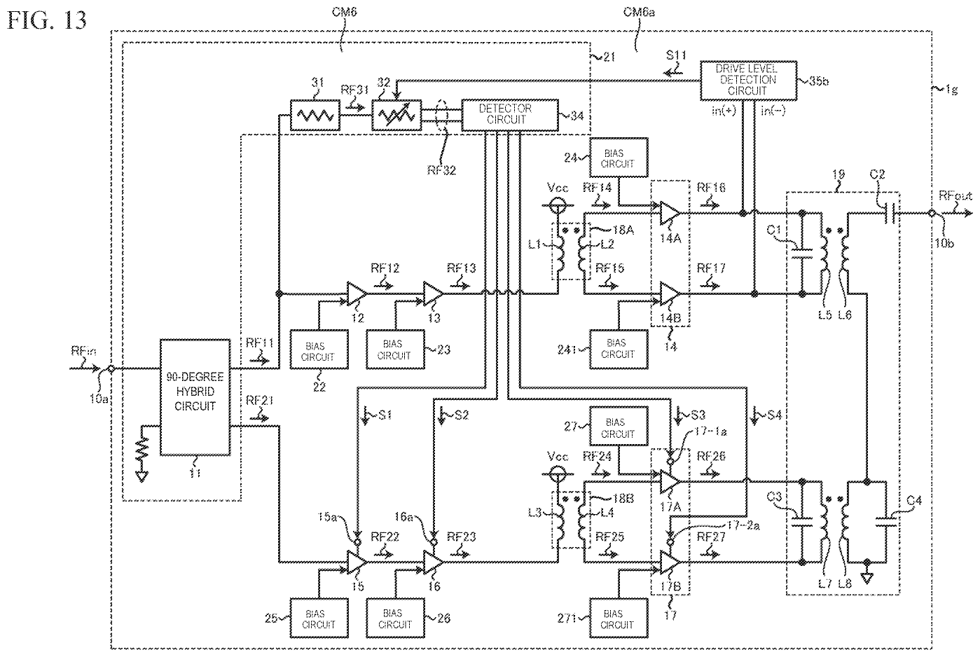

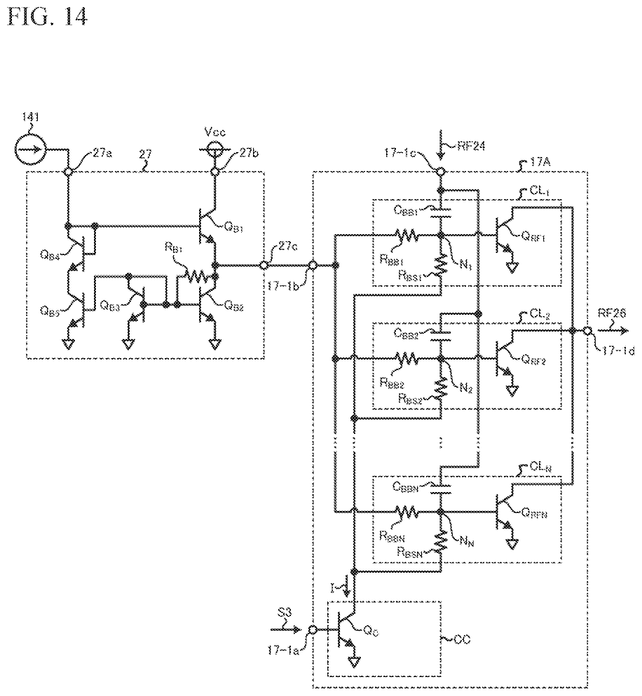

FIG. 13 is a diagram illustrating a configuration of a Doherty amplifier circuit 1g of the eighth embodiment. FIG. 14 is a diagram illustrating a configuration of a peak amplifier in the Doherty amplifier circuit 1g of the eighth embodiment. While FIG. 14 illustrates the peak amplifier 17A of the first phase at the final stage as an example of the peak amplifier included in the Doherty amplifier circuit 1g, other peak amplifiers can also be configured likewise.

The Doherty amplifier circuit 1g includes a control circuit 21. The control circuit 21 includes the attenuator 31, the variable gain control circuit 32, and the detector circuit 34. The control circuit 21 is formed in a first integrated circuit CM6 on a silicon die. A portion of the Doherty amplifier circuit 1g other than the first integrated circuit CM6 on the silicon die is formed in a second integrated circuit CM6a. Moreover, the Doherty amplifier circuit 1g includes a drive level detection circuit 35b. The drive level detection circuit 35b detects a drive level (an operating level) based on the radio-frequency signal RF16 outputted from the carrier amplifier 14A and the radio-frequency signal RF17 outputted from the carrier amplifier 14B.

The detector circuit 34 outputs control signals S1, S2, S3, and S4 to the peak amplifiers 15, 16, 17A, and 17B, respectively, based on the radio-frequency signal RF32. It is exemplified that the detector circuit 34 outputs the control signals S1, S2, S3, and S4 to set each of the peak amplifiers 15, 16, 17A, and 17B to the state of operation when the radio-frequency signal RF32 has a large amplitude. Moreover, it is also exemplified that the detector circuit 34 outputs the control signals S1, S2, S3, and S4 to set each of the peak amplifiers 15, 16, 17A, and 17B to the state of non-operation when the radio-frequency signal RF32 has a small amplitude.

A constant current is inputted from a constant current source 141 to a terminal 27a of the bias circuit 27. A terminal 27b of the bias circuit 27 is electrically connected to the power supply Vcc.

The bias circuit 27 includes transistors QB1, QB2, QB3, QB4, and QB5, and a resistor RB1.

In the present disclosure, the respective transistors are assumed to be bipolar transistors. However, the present disclosure is not limited thereto. A heterojunction bipolar transistor (HBT) is exemplified as such a bipolar transistor. However, the present disclosure is not limited thereto. The transistor may be a field effect transistor (FET), for example. The transistor may be a multi-finger transistor in which multiple unit transistors are electrically connected in parallel. A unit transistor means a minimum structure that constitutes a transistor.

When each of the transistors is an FET, its source corresponds to an emitter of a bipolar transistor, its gate corresponds to a base of the bipolar transistor, and its drain corresponds to a collector of the bipolar transistor.

A collector and a base of the transistor QB4 are electrically connected to the terminal 27a. That is to say, the transistor QB4 is diode connected.

A collector of the transistor QB5 is electrically connected to an emitter of the transistor QB4. An emitter of the transistor QB5 is electrically connected to a reference potential. A ground potential is exemplified as the reference potential. However, the present disclosure is not limited thereto.

A collector of the transistor QB1 is electrically connected to the terminal 27b. A base of the transistor QB1 is electrically connected to the terminal 27a as well as the collector and the base of the transistor QB4. An emitter of the transistor QB1 is electrically connected to a terminal 27c of the bias circuit 27. The transistor QB1 is a transistor which outputs a bias voltage or a bias current.

A collector of the transistor QB2 is electrically connected to the emitter of the transistor QB1 and the terminal 27c. An emitter of the transistor QB2 is electrically connected to the reference potential.

An end of the resistor RB1 is electrically connected to the emitter of the transistor QB1, the terminal 27c, and the collector of the transistor QB2. Another end of the resistor RB1 is electrically connected to a base of the transistor QB2.

A base and a collector of the transistor QB3 are electrically connected to the base of the transistor QB2, the other end of the resistor RB1, and a base of the transistor QB5.

The control signal S3 is inputted from the detector circuit 34 to an enable terminal 17-1a of the peak amplifier 17A. The bias current or the bias voltage is inputted from the bias circuit 27 to a terminal 17-1b of the peak amplifier 17A. The radio-frequency signal RF24 is inputted from the balun 18B to a terminal 17-1c of the peak amplifier 17A. The radio-frequency signal RF26 is outputted from a terminal 17-1d of the peak amplifier 17A to the coupler 19.

The peak amplifier 17A includes cells CL1, CL2, . . . , and CLN. In other words, the peak amplifier 17A is formed from a multi-finger (multi-cell) transistor including the multiple cells. However, the present disclosure is not limited thereto. The peak amplifier 17A may be formed from a single-finger (single-cell) transistor including one cell instead.

The peak amplifier 17A further includes a state control circuit CC that controls to set the state of operation (the state of amplification of the radio-frequency signal) or the state of non-operation (the state of non-amplification of the radio-frequency signal) of each of the cells CL1, CL2, . . . , and CLN. The state control circuit CC includes a transistor QC.

The cell CL1 includes a transistor QRF1, a capacitor CBB1, and resistors RBB1 and RBS1. A unit transistor is exemplified as the transistor QRF1. However, the present disclosure is not limited thereto.

One end of the resistor RBB1 is electrically connected to the terminal 17-1b. That is to say, the resistor RBB1 is emitter-follower connected to the transistor QB1 in the bias circuit 27. Another end of the resistor RBB1 is electrically connected to a node N1. One end of the capacitor CBB1 is electrically connected to the terminal 17-1c. Another end of the capacitor CBB1 is electrically connected to the node N1. A base of the transistor QRF1 is electrically connected to the node N1. An emitter of the transistor QRF1 is electrically connected to the reference potential. A collector of the transistor QRF1 is electrically connected to the terminal 17-1d.

The bias current or the bias voltage is inputted to a base of the transistor QRF1 with the resistor RBB1 interposed therebetween. Meanwhile, the radio-frequency signal RF24 is inputted to the base of the transistor QRF1 with the capacitor CBB1 interposed therebetween. The transistor QRF1 amplifies the radio-frequency signal RF24 and outputs the radio-frequency signal RF26 from its collector to the terminal 17-1d.

One end of the resistor RBS1 is electrically connected to the node N1. Another end of the resistor RBS1 is electrically connected to a collector of the transistor QC.

The cell CL2 includes a transistor QRF2, a capacitor CBB2, and resistors RBB2 and RBS2. A unit transistor is exemplified as the transistor QRF2. However, the present disclosure is not limited thereto. Relations of connection among the transistor QRF2, the capacitor CBB2, a node N2, and the resistors RBB2 and RBS2 are the same as relations of connection among the transistor QRF1, the capacitor CBB1, the node N1, and resistors RBB1 and RBS1, and explanations thereof will be omitted.

The cell CLN includes a transistor QRFN, a capacitor CBBN, and resistors RBBN and RBSN. A unit transistor is exemplified as the transistor QRFN. However, the present disclosure is not limited thereto. Relations of connection among the transistor QRFN, the capacitor CBBN, a node NN, and the resistors RBBN and RBSN are the same as the relations of connection among the transistor QRF1, the capacitor CBB1, the node N1, and resistors RBB1 and RBS1, and explanations thereof will be omitted.

The collector of the transistor QC is electrically connected to the other end of the resistor RBS1, another other end of the resistor RBS2, . . . , and another other end of the resistor RBSN. A base of the transistor QC is electrically connected to the enable terminal 17-1a. The control signal S3 is inputted to the base of the transistor QC. An emitter of the transistor QC is electrically connected to the reference potential.

An operation of the state control circuit CC will be described.

When the control signal S3 is at a high level, the transistor QC is set to an on-state and a current I flows from the node N1, the node N2, . . . , and the node NN to the collector of the transistor QC with the resistor RBS1, the resistor RBS2, . . . , and the resistor RBSN interposed therebetween, respectively. That is to say, the transistor QC withdraws the current I from the node N1, the node N2, . . . , and the node NN.

Since the electric current is withdrawn from the node N1, a voltage drop occurs in the resistor RBB1 on which the withdrawn current flows, and the voltage at the node N1 drops as a consequence. Accordingly, a base voltage drops at the transistor QRF1 and the transistor QRF1 is less able to amplify the radio-frequency signal RF24.

Likewise, since the electric current is withdrawn from the node N2, a voltage drop occurs in the resistor RBB2 on which the withdrawn current flows, and the voltage at the node N2 drops as a consequence. Accordingly, a base voltage drops at the transistor QRF2 and the transistor QRF2 is less able to amplify the radio-frequency signal RF24.

Likewise, since the electric current is withdrawn from the node NN, a voltage drop occurs in the resistor RBBN on which the withdrawn current flows, and the voltage at the node NN drops as a consequence. Accordingly, a base voltage drops at the transistor QRFN and the transistor QRFN is less able to amplify the radio-frequency signal RF24.

That is to say, when the control signal S3 is set to the high level, the peak amplifier 17A transitions to the state of non-operation (the state of non-amplification of the radio-frequency signal).

When the control signal S3 is at a low level, the transistor QC is set to an off-state and the current I does not flow from the node N1, the node N2, . . . , and the node NN to the collector of the transistor QC. That is to say, the transistor QC does not withdraw the current I from the node N1, the node N2, . . . , and the node NN.

Accordingly, the transistor QRF1 can amplify the radio-frequency signal RF24 since the base voltage does not drop. Likewise, the transistor QRF2 can amplify the radio-frequency signal RF24 since the base voltage does not drop. Likewise, the transistor QRFN can amplify the radio-frequency signal RF24 since the base voltage does not drop.

That is to say, when the control signal S3 is set to the low level, the peak amplifier 17A transitions to the state of operation (the state of amplification of the radio-frequency signal).

Here, a location to dispose the state control circuit CC may be away from locations to dispose the cells CL1, CL2, . . . , and CLN because the current I is less susceptible to a temperature difference. Usually, the detector circuit 34 serving as a generator of the control signal S3 is disposed at a distance from each of the peak amplifiers 17A and 17B serving as the final-stage amplifiers. Accordingly, the peak amplifiers 17A and 17B which are required to output high electric power and are therefore apt to reach a high temperature and the detector circuit 34 often cause temperature differences. As a consequence, a threshold voltage of a transistor disposed in the vicinity of the peak amplifiers 17A and 17B is apt to be lower as compared to a threshold voltage of a transistor disposed in the vicinity of the detector circuit 34. Here, when the state control circuit CC is disposed in the vicinity of the peak amplifiers 17A and 17B, the threshold voltage of the transistor QC included in the state control circuit CC drops due to a rise in temperature in the vicinity of the peak amplifiers 17A and 17B. In other words, when the state control circuit CC is disposed in the vicinity of the locations to dispose the cells CL1, CL2, . . . , and CLN, there is a possibility of false recognition by the state control circuit CC that “the control signal S3 is at the high level” even when the control signal S3 generated by the detector circuit 34 is actually at the low level. On the other hand, when the state control circuit CC is disposed away from the locations to dispose the cells CL1, CL2, . . . , and CLN, it is possible to suppress the drop in threshold voltage of the transistor QC included in the state control circuit CC. Accordingly, the false recognition by the state control circuit CC concerning the control signal S3 is easily prevented. For example, the state control circuit CC may be disposed in the control circuit 21. In this case, it is possible to consider that the current I corresponds to the control signal S3.

On the other hand, a location to dispose the resistor RBB1 is preferably close to a location to dispose the transistor QRF1 because the voltage is susceptible to a parasitic capacitance. If the location to dispose the resistor RBB1 is away from the location to dispose the transistor QRF1, transmission of a voltage drop that occurs in the resistor RBB1 to the base of the transistor QRF1 is slowed down. In other words, switching between the state of operation and the state of non-operation of the transistor QRF1 is slowed down. Accordingly, the location to dispose the resistor RBB1 is preferably close to the location to dispose the transistor QRF1 in order to speed up the switching of the state of the transistor QRF1. The same applies to other cells.

### Effects

The switching is slowed down when the bias circuit 27 is configured to control the state of operation (the state of amplification of the radio-frequency signal) and the state of non-operation (the state of non-amplification of the radio-frequency signal) of the peak amplifier 17A by changing the bias current or the bias voltage as in the technique disclosed in U.S. Patent Application Publication No. 2016/0241209, for example, because it takes time to change the direct current (the bias current) or the direct-current voltage (the bias voltage).

On the other hand, it is possible to control the state of operation and the state of non-operation of the peak amplifier 17A by inputting the control signal S3 either at the high level or at the low level to the enable terminal 17-1a. Accordingly, the bias circuit 27 does not have to change the bias current or the bias voltage.

Thus, the peak amplifier 17A can speed up the switching between the state of operation and the state of non-operation.

Meanwhile, the peak amplifier 17A can control the state of operation and the state of non-operation of the peak amplifier 17A by causing the state control circuit CC to withdraw the current I from the node N1, the node N2, . . . , and the node NN.

As described above, since the peak amplifier 17A can control the state of operation and the state of non-operation by withdrawing the current I, the peak amplifier 17A can speed up the switching as compared to the control of the state of operation and the state of non-operation by using the voltage.

Concerning the description of the claims, the present disclosure can adopt the following aspects.

(1) A Doherty amplifier circuit including:
a first integrated circuit; and
a second integrated circuit connected to the first integrated circuit, in which
one of the first integrated circuit and the second integrated circuit includes
   a carrier amplifier that amplifies a radio-frequency signal,
   a peak amplifier that amplifies the radio-frequency signal, and
   a variable gain control circuit that controls a gain of the radio-frequency signal based on a drive level signal that indicates a drive level of the carrier amplifier,
a state of operation of the peak amplifier is controlled based on an output from the variable gain control circuit, and
the first integrated circuit on a silicon die includes at least the variable gain control circuit.

(2) The Doherty amplifier circuit according to (1), further including:
a bias circuit that inputs a bias based on the output from the variable gain control circuit to the peak amplifier.

(3) The Doherty amplifier circuit according to (2), in which the first integrated circuit on the silicon die further includes:
an active balun that accepts the output from the variable gain control circuit as an input, and
a detector circuit that accepts a signal that passes through the active balun as an input and outputs a signal to control the bias circuit.

(4) The Doherty amplifier circuit according to any one of (1) to (3), in which
the carrier amplifier includes
   a driver stage carrier amplifier, and
   a power stage carrier amplifier that accepts an output from the driver stage carrier amplifier as an input,
the peak amplifier includes
   a driver stage peak amplifier, and
   a power stage peak amplifier that accepts an output from the driver stage peak amplifier as an input,
the first integrated circuit on the silicon die further includes
   a distribution circuit that inputs the radio-frequency signal to the carrier amplifier and to the peak amplifier as signals having different phases from each other,
   the driver stage carrier amplifier, and
   the driver stage peak amplifier.

(5) The Doherty amplifier circuit according to any one of (1) to (4), further including:
a multiplier that multiplies and outputs the radio-frequency signal;
a variable phase shifter that controls a phase of the output signal from the multiplier; and
a frequency divider that divides a frequency of the output from the variable phase shifter, in which
the Doherty amplifier circuit inputs the radio-frequency signal and an output signal from the frequency divider to the carrier amplifier and to the peak amplifier as signals having different phases from each other.

(6) The Doherty amplifier circuit according to (5), further including:
a control circuit that outputs a control signal based on an output signal from the carrier amplifier and on an output signal from the peak amplifier, and
an amount of phase shift of the variable phase shifter is controlled by the output signal from the control circuit.

(7) The Doherty amplifier circuit according to (3), further including:
a variable current source that is controlled based on the output from the detector circuit, in which
an output from the variable current source is used as the signal to control the bias circuit.

What is claimed is:

1. A Doherty amplifier circuit comprising:
a first integrated circuit; and
a second integrated circuit connected to the first integrated circuit,
wherein the first integrated circuit comprises:
a carrier amplifier configured to amplify a radio-frequency signal,
a peak amplifier configured to amplify the radio-frequency signal, and
a variable gain control circuit configured to control a gain of the radio-frequency signal based on a drive level signal that indicates a drive level of the carrier amplifier,
wherein a state of operation of the peak amplifier is controlled based on an output from the variable gain control circuit, and
wherein the first integrated circuit is on a silicon die.

2. The Doherty amplifier circuit according to claim 1, further comprising:
a bias circuit configured to input a bias to the peak amplifier based on the output from the variable gain control circuit.

3. The Doherty amplifier circuit according to claim 2, wherein the first integrated circuit on the silicon die further comprises:
an active balun configured to accept the output from the variable gain control circuit as an input, and
a detector circuit configured to accept a signal that passes through the active balun as an input and to output a signal to control the bias circuit.

4. The Doherty amplifier circuit according to claim 1,
wherein the carrier amplifier comprises:
a driver stage carrier amplifier, and
a power stage carrier amplifier configured to accept an output from the driver stage carrier amplifier as an input,
wherein the peak amplifier comprises:
a driver stage peak amplifier, and
a power stage peak amplifier configured to accept an output from the driver stage peak amplifier as an input, and
wherein the first integrated circuit on the silicon die further comprises:
a distribution circuit configured to input the radio-frequency signal to the carrier amplifier and to the peak amplifier as signals having different phases from each other,
the driver stage carrier amplifier, and
the driver stage peak amplifier.

5. The Doherty amplifier circuit according to claim 2,
wherein the carrier amplifier comprises:
a driver stage carrier amplifier, and
a power stage carrier amplifier configured to accept an output from the driver stage carrier amplifier as an input,
wherein the peak amplifier comprises:
a driver stage peak amplifier, and
a power stage peak amplifier configured to accept an output from the driver stage peak amplifier as an input, and
wherein the first integrated circuit on the silicon die further comprises:
a distribution circuit configured to input the radio-frequency signal to the carrier amplifier and to the peak amplifier as signals having different phases from each other,
the driver stage carrier amplifier, and
the driver stage peak amplifier.

6. The Doherty amplifier circuit according to claim 1, further comprising:
a multiplier configured to multiply and to output the radio-frequency signal;
a variable phase shifter configured to control a phase of the output signal from the multiplier; and
a frequency divider configured to divide a frequency of the output from the variable phase shifter,
wherein the Doherty amplifier circuit is configured to input the radio-frequency signal and an output signal from the frequency divider to the carrier amplifier and to the peak amplifier as signals having different phases from each other.

7. The Doherty amplifier circuit according to claim 2, further comprising:
a multiplier configured to multiply and to output the radio-frequency signal;
a variable phase shifter configured to control a phase of the output signal from the multiplier; and
a frequency divider configured to divide a frequency of the output from the variable phase shifter,
wherein the Doherty amplifier circuit is configured to input the radio-frequency signal and an output signal from the frequency divider to the carrier amplifier and to the peak amplifier as signals having different phases from each other.

8. The Doherty amplifier circuit according to claim 6, further comprising:
a control circuit configured to output a control signal based on an output signal from the carrier amplifier and based on an output signal from the peak amplifier,
wherein an amount of phase shift of the variable phase shifter is controlled by the output signal from the control circuit.

9. The Doherty amplifier circuit according to claim 3, further comprising:
a variable current source that is controlled based on the output from the detector circuit,
wherein an output from the variable current source is the signal that controls the bias circuit.
